(19) United States
(12) Patent Application Publication
(10) Pub. No.: US 2021/0184652 A1
(43) Pub. Date: Jun. 17, 2021

(54) MANUFACTURING OF C-AXIS TEXTURED SIDEWALL ALN FILMS

(71) Applicants: University of Florida Research Foundation, Incorporated, Gainesville, FL (US); OEM Group, LLC, Gilbert, AZ (US)

(72) Inventors: Roozbeh Tabrizian, Gainesville, FL (US); Farid S. Alokozai, Scottsdale, AZ (US)

(21) Appl. No.: 17/119,557

(22) Filed: Dec. 11, 2020

Related U.S. Application Data
(60) Provisional application No. 62/947,695, filed on Dec. 13, 2019.

(51) Int. Cl. H03H 9/17; H03H 3/02; H03H 9/02; H03H 9/13

(52) U.S. Cl. CPC H03H 9/172; H03H 3/02; H03H 9/176; H03H 9/13; H03H 9/02031

(57) ABSTRACT

A method for fabricating an acoustic wave resonator includes, in part, forming a micro-fin structure that includes one or more sidewalls on a substrate. The sidewalls are thereafter annealed. A bottom electrode layer is then deposited on top of the micro-fin structure. Afterwards, a layer of aluminum nitride is formed on the bottom electrode layer where the layer of aluminum nitride includes a textured aluminum nitride layer with a c-axis substantially perpendicular to the one or more sidewalls. A top electrode layer is then formed on top of the layer of aluminum nitride. In addition, the top electrode layer can be patterned, and the layer of aluminum nitride can be etched to provide access windows to the bottom electrode layer.

### CROSS-REFERENCE TO RELATED APPLICATIONS

This patent application claims priority to Provisional Application Ser. No. 62/947,695, filed Dec. 13, 2019, which is incorporated herein by reference in its entirety.

### GOVERNMENT SUPPORT

This invention was made with government support under 1752206 awarded by the National Science Foundation. The government has certain rights in the invention.

### BACKGROUND

Dense integration of multi-frequency and multi-band acoustic spectral processor is essential for realization of the emerging ultra-wideband mobile communication systems that operate based on carrier aggregation. These systems require a large set of resonators with frequencies over ultra- and super-high-frequency regimes to enable spread-spectrum data communication with minimum latency. Current radio frequency bulk acoustic wave (BAW) resonator technologies rely on planar architectures, such as film bulk acoustic resonators (FBAR) or solidly mounted resonators (SMR), with large surfaces to accommodate the required electromechanical transduction area for low-loss operation. The frequency of planar BAW resonators is tied to the thickness of the piezoelectric transducer film that is constant across the substrate. This limitation prevents single-chip integration of multi-frequency and multi-band spectral processors needed for carrier aggregation. Furthermore, planar BAW resonators occupy large chip area since their loss is inversely proportional to the electrode surface dimensions of the piezoelectric film. This becomes more pronounced in carrier aggregation schemes that require several spectral processors at various frequencies and impose excessive integration costs and challenges. An alternative architecture that miniaturizes the planar footprint relies on integration of aluminum nitride (AlN) piezoelectric film transducers on the sidewall of silicon fins to realize high-performance fin bulk acoustic resonators (FinBAR). FinBARs enable ultra-dense integration of high Q resonators and filters in a small chip footprint. Furthermore, operating in width-extensional bulk acoustic modes, their frequency can be lithographically tailored over wide spectrums in ultra- and super-high-frequency regimes.

### SUMMARY

Embodiments are directed to a method of fabricating a fin bulk acoustic wave resonator (FinBAR). In some embodiments, the method comprises forming a micro-fin structure on a substrate, the micro-fin structure comprising one or more sidewalls. In some embodiments, the method further comprises smoothing the one or more sidewalls. In some embodiments, the method further comprises depositing a bottom electrode layer on top of the micro-fin structure. In some embodiments, the method further comprises forming a layer of aluminum nitride (AlN) on the bottom electrode layer, where a c-axis of the aluminum nitride layer is substantially perpendicular to the one or more sidewalls of the micro-fin structure. In some embodiments, the method further comprises forming a top electrode layer on top of the layer of aluminum nitride (AlN). In some embodiments, the method further comprises patterning the top electrode layer and etching the layer of aluminum nitride (AlN) to create access windows to the bottom electrode layer.

In some embodiments, the substrate and micro-fin structure comprise silicon.

In some embodiments, smoothing the one or more sidewalls comprises annealing.

In some embodiments, the annealing comprises hydrogen (H₂) at 1100C.

In some embodiments, smoothing the one or more sidewalls comprises treatment in RF plasma discharge at a power of 70W providing argon (Ar) ion bombardment.

In some embodiments, the bottom electrode layer comprises molybdenum (Mo).

In some embodiments, the method further comprises depositing a seed layer of aluminum nitride (AlN) on the micro-fin structure. In some embodiments, the molybdenum (Mo) comprised in the bottom electrode is sputtered on the seed layer.

In some embodiments, the bottom electrode layer comprises platinum (Pt).

In some embodiments, the platinum (Pt) has a thickness of about 30 nanometers.

In some embodiments, the top electrode layer comprises molybdenum (Mo) with a thickness of about 50 nanometers.

In some embodiments, the micro-fin structure is formed using a deep reactive ion etching technique. In some embodiments, the micro-fin structure is formed using a number of cycles with each cycle comprising a nearly isotropic etching step and a step of deposition of a passivation layer.

In some embodiments, the layer of aluminum nitride has a thickness of about 720 nanometers. In some embodiments, the aluminum nitride layer is formed by a reactive sputtering technique at a base pressure of less than 2×10⁻¹⁰ bar and a power of about 5.5 kW.

In some embodiments, the reactive sputtering technique uses Argon (Ar) and nitrogen (N₂) gas flows of about 3 and 15 standard cubic centimeters per minute (SCCM) respectively.

In some embodiments, the layer of aluminum nitride is etched using a tetramethylammonium hydroxide (TMAH) solution at about 50° C. as an etchant to create the access windows to the bottom electrode layer.

### BRIEF DESCRIPTION OF THE DRAWINGS

So that the present disclosure can be understood by those of ordinary skill in the art, a more detailed description can be had by reference to aspects of some illustrative embodiments, some of which are shown in the accompanying drawings.

FIG. 1 is a block diagram of an exemplary acoustic wave resonator system, in accordance with some embodiments.

FIGS. 2A-2E illustrate Scanning Electron Microscopy (SEM) images of exemplary substrate and micro-fin structure, according to some embodiments.

FIG. 3 compares electron microscopy images of different acoustic wave resonators, in accordance with some embodiments.

FIG. 4 compares high-resolution XTEM, over selective locations across the thickness of exemplary sidewall AlN films, in accordance with some embodiments.

FIG. 5 shows SEM images and compares the surface roughness of exemplary sidewall AlN films in accordance with some embodiments.

FIG. 6 compares the TEM images of exemplary sidewall bottom electrodes, in accordance with some embodiments.

FIG. 7 compares the TEM images of exemplary AlN layers deposited on the bottom electrodes, in accordance with some embodiments.

FIG. 8 compares the surface roughness of different exemplary embodiments.

FIGS. 9A and 9B illustrate an exemplary acoustic wave resonator, in accordance with some embodiments, and its admittance, respectively.

In accordance with common practice some features illustrated in the drawings cannot be drawn to scale. Accordingly, the dimensions of some features can be arbitrarily expanded or reduced for clarity. In addition, some of the drawings cannot depict all of the components of a given system, method or device. Finally, like reference numerals can be used to denote like features throughout the specification and figures.

### DETAILED DESCRIPTION

Reference will now be made in detail to embodiments, examples of which are illustrated in the accompanying drawings. In the following detailed description, numerous specific details are set forth in order to provide a thorough understanding of the some described embodiments. However, it will be apparent to one of ordinary skill in the art that the some described embodiments may be practiced without these specific details. In other instances, well-known methods, procedures, components, circuits, and networks have not been described in detail so as not to unnecessarily obscure aspects of the embodiments.

It will also be understood that, although the terms first, second, etc. are, in some instances, used herein to describe some elements, these elements should not be limited by these terms. These terms are only used to distinguish one element from another. For example, a first contact could be termed a second contact, and, similarly, a second contact could be termed a first contact, without departing from the scope of the some described embodiments. The first contact and the second contact are both contacts, but they are not the same contact, unless the context clearly indicates otherwise.

The terminology used in the description of the some described embodiments herein is for the purpose of describing particular embodiments only and is not intended to be limiting. As used in the description of the some described embodiments and the appended claims, the singular forms “a,”, “an,” and “the” are intended to comprise the plural forms as well, unless the context clearly indicates otherwise. It will also be understood that the term “and/or” as used herein refers to and encompasses any and all possible combinations of one or more of the associated listed items. It will be further understood that the terms “comprises,” “comprising,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” is, optionally, construed to mean “when” or “upon” or “in response to determining” or “in response to detecting,” depending on the context. Similarly, the phrase “if it is determined” or “if [a stated condition or event] is detected” is, optionally, construed to mean “upon determining” or “in response to determining” or “upon detecting [the stated condition or event]” or “in response to detecting [the stated condition or event],” depending on the context.

It should be appreciated that in the development of any actual embodiment (as in any development project), numerous decisions must be made to achieve the developers' specific goals (e.g., compliance with system and business-related constraints), and that these goals will vary from one embodiment to another. It will also be appreciated that such development efforts might be complex and time consuming but would nevertheless be a routine undertaking for those of ordinary skill in the art of FinBAR having the benefit of this disclosure.

FinBARs are ideally poised to provide a superior k_{eff}² (effective electromechanical coefficient) and Q (quality factor), compared to planar BAW and contour mode resonators, due to the low acoustic dissipation in Si and the large piezoelectric coefficient d₃₃ of AlN (Aluminum Nitride) sidewall transducer film. In practice, however, the performance of FinBAR is limited by the texture and crystalline orientation of sidewall AlN film.

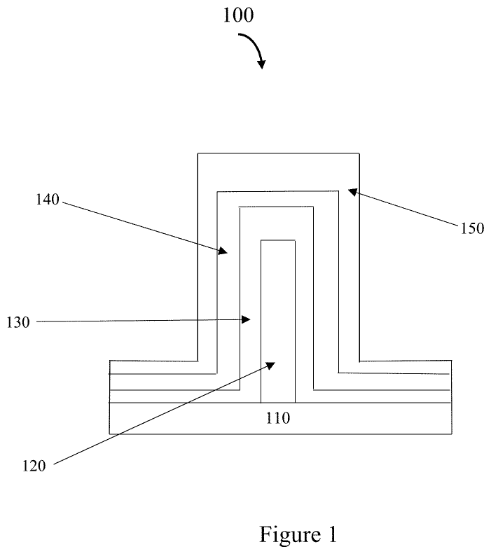

Referring to FIG. 1, a cross-sectional view of an acoustic wave resonator 100 is illustrated, in accordance with some embodiments. Acoustic wave resonator system 100 is shown as including, in part, a substrate 110, a micro-fin structure 120, a bottom electrode layer 130, an aluminum nitride layer 140, and a top electrode layer 150. In some embodiments, the bottom electrode layer 130 is positioned above the substrate 110 and the micro-fin structure 120. In some embodiments, the bottom electrode layer 130 covers at least portions of the substrate 110 and the micro-fin 120.

In some embodiments, the aluminum nitride layer 140 is positioned above the bottom electrode layer 130. In some embodiments, the aluminum nitride layer 140 covers at least portions of the bottom electrode layer 130. In some embodiments, the aluminum nitride layer 140 comprises textured sidewall AlN films. A c-axis orientation of the textured sidewall AlN films is substantially perpendicular to one or more sidewalls of the micro-fin 120. That is, the crystalline orientation of the textured sidewall AlN films is substantially perpendicular to the one or more sidewalls of the micro-fin 120. In some embodiments, the aluminum nitride layer 140 comprises densely textured AlN films with substantially perpendicular (e.g., 90°±5° in some embodiments) c-axis on the one or more sidewalls of the micro-fin 120. In some embodiments, the top electrode layer 150 is positioned above the aluminum nitride layer 140. In some embodiments, the top electrode layer 150 covers at least portions of the aluminum nitride layer 140.

Described otherwise, a micro-fin structure is formed on a substrate, the micro-fin structure comprising one or more sidewalls. The sidewalls are smoothed. In some embodiments, a seed layer of aluminum nitride (AlN) is deposited on the micro-fin structure. In some embodiments, a bottom electrode layer is deposited on top of the seed layer. A layer of aluminum nitride (AlN) is formed on the bottom electrode layer, where a c-axis orientation of the layer of aluminum nitride is substantially perpendicular to the one or more sidewalls of the micro-fin structure. A top electrode layer is formed on top of the layer of aluminum nitride (AlN). In some embodiments, the top electrode layer is patterned, and the layer of aluminum nitride (AlN) is etched to create access windows to the bottom electrode layer. It should be noted that, in various embodiments, the steps to fabricate different components and layers of the disclosed acoustic wave resonator can take place in different order.

In some embodiments, the bottom electrode layer 130 covers at least portions of: a top surface of the substrate 110, a top surface of the micro-fin 120, and sidewalls of the micro-fin 120. In some embodiments, the substrate 110 comprises silicon. In some embodiments, the micro-fin 120 forms a pin-shape over the substrate 110. The micro-fin may comprise silicon.

The micro-fin may be fabricated by a deep reactive ion etching (DRIE) technique. DRIE is a highly anisotropic etch process used to create deep penetration, steep-sided holes and trenches in wafers/substrates. DRIE typically creates structures with high aspect ratios. In some embodiments, a Bosch DRIE is used to fabricate the micro-fin 120. The Bosch DRIE process can fabricate 90° (truly vertical) sidewalls. The Bosch process (also known as pulsed or time-multiplexed etching), alternates repeatedly between two modes, i.e., an etching mode and a depositing mode, to achieve nearly vertical micro-fins. The etching mode comprises a standard, nearly isotropic plasma etches. The plasma contains some ions, which attack the wafer from a nearly vertical direction. Sulfur hexafluoride is often used for silicon. The depositing mode comprises deposition of a chemically inert passivation layer. Each phase lasts for several seconds. A resulted passivation layer protects the entire substrate from further chemical attack and prevents further etching. However, during the etching phase, directional ions that bombard the substrate attack the passivation layer at the bottom of the trench (but not along the sides). The ions collide with the bottom of the trench and sputter it off, exposing the substrate to the chemical etchant. These etch/deposit steps are repeated many times over resulting in many very small isotropic etch steps taking place only at the bottom of the etched pits.

In some embodiments, the acoustic wave resonator system 100 is fabricated on (110) Si substrate. In some embodiments, and due to a finite number of isotropic etch and passivation cycles, sidewall surface of the micro-fin 120 suffers from roughness and scalloping. In order to reduce adverse effect of surface roughness, in some embodiments, hydrogen (H₂) annealing at temperature between 650C.-1300° C. is used to smoothen the sidewalls of the micro-fin 120.

In some embodiments, the bottom electrode layer 130 comprises platinum (Pt). In some embodiments, a crystalline Pt layer is formed over portions of the substrate 110 and the micro-fin 120. The Pt layer may be deposited via an atomic layer deposition (ALD) method. In some embodiments, the ALD deposition takes place at temperature greater than 100° C. For example, the ALD deposition may take place at about 150° C. In some embodiments, the thickness of the crystalline Pt layer may be 30 nanometers.

In some other embodiments, the bottom electrode layer 130 comprises molybdenum (Mo). In some embodiments, the bottom electrode layer 130 comprises sputtered Mo deposited on a aluminum nitride (AlN) seed layer. The aluminum nitride seed layer and the Mo thin film can be formed via a physical vapor deposition (PVD) clustering method. The PVD method may be employed by an AC powered S-gun magnetron method and a DC powered S-gun magnetron method for deposition of the aluminum nitride seed layer and the Mo thin film, respectively. In some embodiments, a 20-nanometer thick AlN seed layer is formed by the PVD method. In some embodiments, the aluminum nitride seed layer is formed by the AC powered S-gun magnetron with a power of greater than 1 kW.

In some embodiments, prior to forming the aluminum nitride layer 140, the acoustic wave resonator system 100 is treated in a radio frequency (RF) plasma discharge. The RF plasma discharge may take place at power between 50W-300W. The RF plasma discharge uses argon (Ar) ion bombardment to atomically smoothen the acoustic wave resonator system 100. In some embodiments, the RF plasma discharge smoothen surfaces of the micro-fin 120. In some embodiments, the RF plasma discharge is followed by forming the aluminum nitride layer 140. The aluminum nitride layer 140 may comprise aluminum nitride (AlN). In some embodiments, the aluminum nitride layer 140 is so formed that a c-axis of the aluminum nitride layer 140 is substantially perpendicular to the sidewalls of the micro-fin 120. In some embodiments, the aluminum nitride layer 140 is formed via a reactive sputtering. The reactive sputtering can take place at a base pressure of less than about 2×10¹⁰ bar with a power greater than 3 kW, for example, with a power of 5.5 kW.

In some embodiments, the reactive sputtering uses Ar and nitrogen (N₂) gas. In some embodiments, the Ar and N₂ flow rates are at the ratio of about 1:3. In some embodiments, the Ar and N₂ gas flows of about 5 and 17 standard cubic centimeters per minute (SCCM) are used respectively. In some embodiments, the Ar and N₂ gas flows of about 3 and 15 SCCM are used respectively.

In some embodiments, the aluminum nitride layer 140 is formed via a PVD clustering method. The PVD method may be employed by an AC powered S-gun magnetron method. In some embodiments, the aluminum nitride layer 140 is formed by the AC powered S-gun magnetron with a power of greater than 1 kW.

In some embodiments, the top electrode layer 150 may comprise molybdenum (Mo), Ti, Ta, Ag, Au, etc. In some embodiments, the top electrode layer 150 is formed via a PVD clustering method. The PVD method may be employed by a DC powered S-gun magnetron method. In some embodiments, a Mo layer with a thickness of about 150 nanometers is formed by the PVD method. In some embodiments, the top electrode layer 150 is formed by the DC powered S-gun magnetron with a power of greater than 1 kW, for example, with a DC power of about 3 kW.

In some embodiments, portions of the top electrode layer 150 on the sidewalls of the micro-fin 120 are patterned. The patterned portions of the top electrode layer 150 form a first electrode. In some embodiments, portions of the aluminum nitride layer 140 on the sidewalls of the micro-fin 120 are etched. The etching process exposes portions of the bottom electrode layer 130. In some embodiments, the exposed portions of the bottom electrode layer 130 serve as a second electrode.

In some embodiments, portions of the aluminum nitride layer 140 are etched. A tetramethylammonium hydroxide (TMAH) solution can be used to etch the portions of the aluminum nitride layer 140. The etching process can take place at temperature greater than or about 50° C.

A challenge with characterization of the sidewalls of the aluminum nitride layer is the incapability of X-ray diffraction (XRD) for morphological study. This limitation is due to the small sidewall surface of micro-fins, i.e., the micro-fin, compared to the spot size of the optical ray, which prevents from local characterization of crystal content and orientation. In the absence of XRD results for the sidewalls of the aluminum nitride layer, i.e., the AlN films, selected-area diffraction patterns, extracted from Transmission Electron Microscopy (TEM) images, are used. A detailed set of bright-field cross-sectional transmission electron microscopy (BF-XTEM) images, taken across the sidewall film thickness, are used to identify the relative quality of the films over process variations, and also when compared with the films deposited on the planar surfaces in the same deposition run.

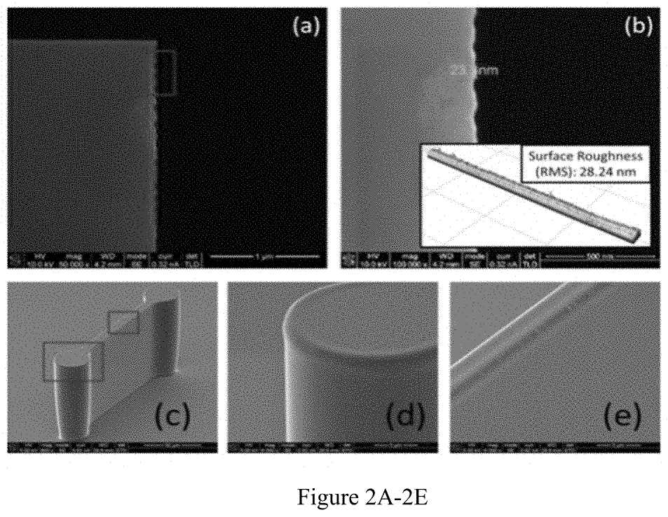

FIGS. 2A-2E illustrate Scanning Electron Microscopy (SEM) images of the substrate and the micro-fin, according to some embodiments. FIG. 2(a) shows the cross-sectional SEM of the Si micro-fins, e.g., the substrate and the micro-fin, after DRIE, highlighting a scallop depth of 23 nm. FIG. 2(b) shows the sidewall topography measured using an optical profilometer tool, highlighting a surface roughness of about 28 nanometers in root-mean-square (rms). While achieving a high quality AlN films requires sub-1 nanometer surface roughness, high temperature H2 annealing is used to smoothen sidewalls. FIGS. 2(c-e) show the micro-fins after H₂ annealing process. Smooth sidewall surfaces at different regions can be seen on those SEM images.

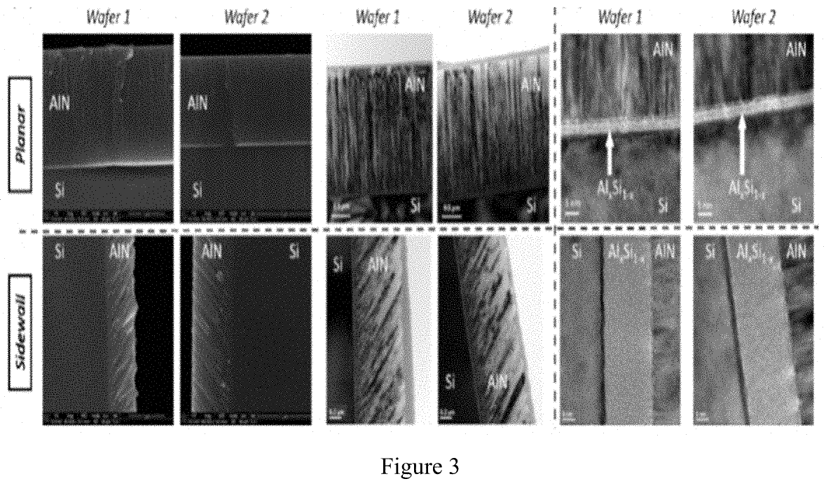

FIG. 3 compares electron microscopy images of different acoustic wave resonators, in accordance with some embodiments. The two processes used for deposition of AlN on these embodiments differentiated in the Ar and N₂ pressures. For wafer 1, the Ar and N₂ gas flows of about 5 and 17 SCCM are used respectively (process 1). For wafer 2, the Ar and N₂ gas flows are reduced to about 3 and 15 SCCM respectively (process 2). In both wafers, the thickness of sidewall AlN films was nearly a third of the planar AlN films. The slower deposition rate on the sidewall can be attributed to the geometric factor reducing flux of sputter species to the sidewall compared to a plane wafer surface. It is evident that sputtering on sidewall results in tilted grains. Such titled growth can be attributed to the reduced mobility of ad-atoms on the sidewall and the increasing roughness of the film over the thickness. These in turn correspond to the non-perpendicular direction of the deposition flux and slowed nucleation of the sidewall film that resulted in growth of thick amorphous aluminum silicide (AlₓSi₁₋ₓ) layer at the interface with Si surface. This can be clearly observed comparing the images of the planar and sidewall films in both processes. While the AlₓSi₁₋ₓ layer thickness is only about 2 nanometers in planar films, its thickness increases to about 20 nanometers on the sidewall. The thicker amorphous AlₓSi₁₋ₓ layer results in excessive roughness of the sidewall surface, which in turn promotes tilted growth in individual grains.

Comparing the images for two processes it is evident that change in sputtering gas pressure significantly reduces the tilt angle of the grains. While the tilt angle of sidewall AlN grains in one process, e.g., wafer 1, is about 41°, it is about 53° for the other process, e.g., wafer 2, with different deposition pressure.

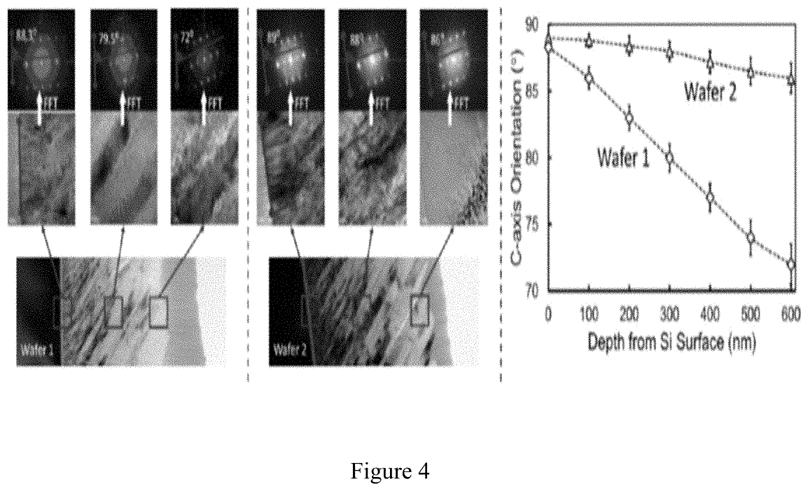

FIG. 4 compares the high-resolution XTEM, over selective locations across the thickness of exemplary sidewall AlN films, in accordance with some embodiments. C-axis orientation, with respect to the surface is extracted for twenty locations uniformly distributed over the sidewall film thickness. The c-axis orientation deviates from sidewall surface normal with thickness increase. C-axis orientations of 80.15°±8.15° for wafer 1 and 87.5°±1.5° for wafer 2 are extracted across the sidewall film thickness. This result highlights the significant improvement in normal orientation and cross-thickness consistency of sidewall AlN c-axis with the reduction of sputtering pressure.

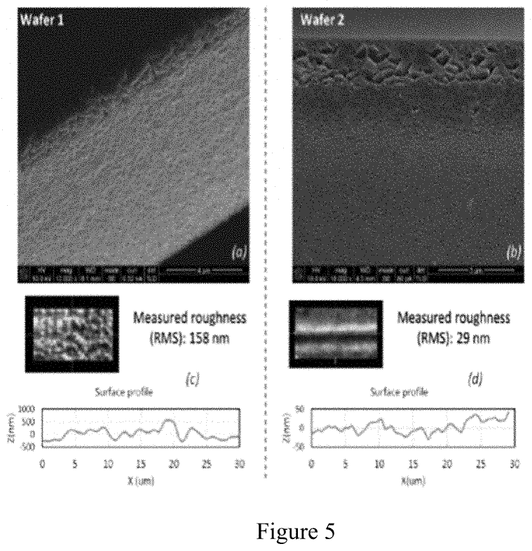

FIG. 5 shows the SEM and compares the surface roughness of the sidewall AlN films in accordance with some embodiments. The sidewall films have significantly higher roughness compared to planar counterparts in both wafers. This is due to the granular growth of sidewall films. Furthermore, the surface roughness is significantly decreased by reducing the sputtering pressure in the process 2. While a surface roughness of about 158 nanometers (rms) is measured on the sidewall film in wafer 1, reducing the sputtering pressure results in a surface roughness of about 29 nanometers (rms) in wafer 2.

In some embodiments, following the optimization of the sputtering process on Si micro-fins, wafers are used to explore the effect of different bottom electrodes on the texture and crystallinity of the sidewall films. Considering the higher quality of sidewall films sputtered at lower pressure, the process 2 is used for AlN deposition, in some embodiments. It is well-known that addition of bottom electrode tremendously affects the quality of sputtered piezoelectric film. The choice of bottom electrode material and deposition methodology is identified to ensure crystalline texture of the metallic film. In some embodiments, a 30 nanometers Pt layer that is deposited on (110) Si shows a dominant (111) texture (0.1° FWHM on the top surface). In some embodiments, a seed AlN layer of about 10-40 nanometers is sputtered on the sidewall, using the process 2, to promote (110)-crystalline growth of the bottom Mo layer.

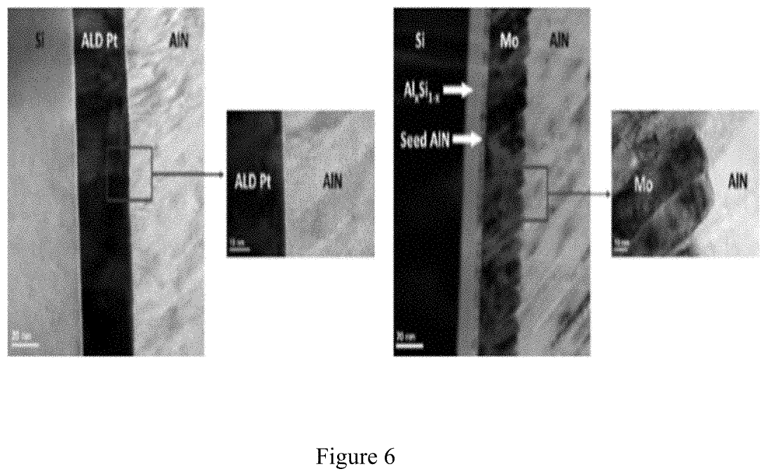

FIG. 6 compares the TEM images of the sidewall bottom electrodes, in accordance with some embodiments. While the ALD-deposited Pt layer has created a sharp interface with Si sidewall surface, the amorphous AlₓSi₁₋ₓ layer with a thickness of 20 nanometers is evident in some embodiments with a seeded AlN layer of about 20 nanometers, and results in granular growth of bottom Mo with large roughness.

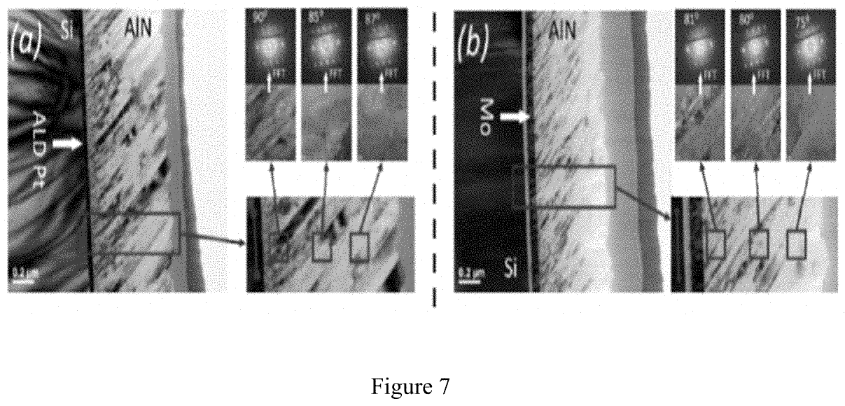

FIG. 7 compares the TEM images of the subsequent AlN layers deposited on the bottom electrodes, in accordance with some embodiments. While in some embodiments, ALD-deposited Pt layer electrode shows a crystalline texture across the sidewall film thickness. In some other embodiments, the quality of sidewall AlN is substantially degraded as a result of bottom Mo roughness. A c-axis orientation of about 88.5°±1.5° and about 78°±3° is measured for some embodiments, respectively. Besides, the arc-angle of 12°+2° and 24° are measured for wafers in those embodiments, respectively. While the quality of the sidewall film in some embodiments is not suitable for implementation of FinBARs, the other embodiments that utilize the ALD-deposited Pt layer as the bottom electrode show a comparable crystallinity to wafer 2 of FIG. 4 (no bottom electrode).

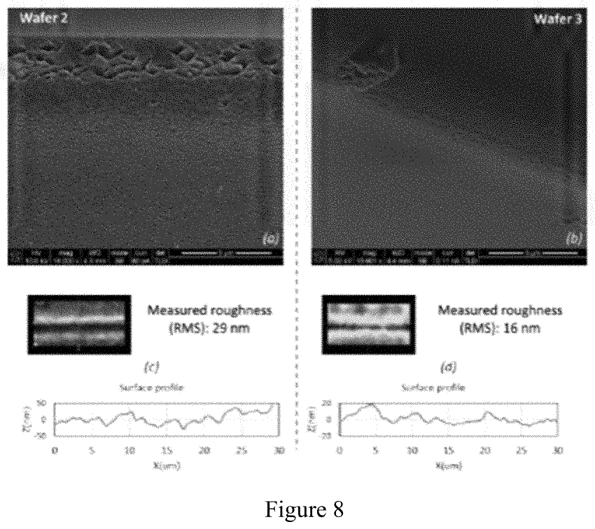

FIG. 8 compares the surface roughness of different embodiments. While a similar c-axis orientation and crystallinity is observed in wafers 2 and 3, the addition of Pt bottom electrode has considerably reduced the surface roughness from 29 nanometers rms (wafer 2) to 16 nanometers rms (wafer 3). This improvement can be attributed to the effect of Pt layer as the diffusion barrier that prevents from formation of the rough and amorphous AlₓSi₁₋ₓ layer at Si interface.

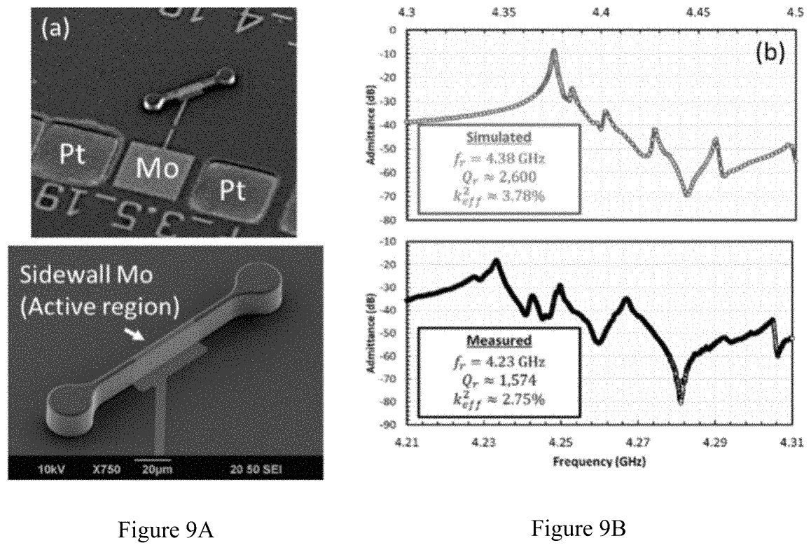

FIGS. 9A and 9B illustrate an exemplary acoustic wave resonator, in accordance with some embodiments, and its admittance, respectively. FinBARs are fabricated on wafer 3 through deposition and patterning of sidewall Mo electrodes and opening access to bottom Pt electrode. FIG. 9(a) shows the SEM image of a FinBAR with about 2200 nanometers-wide fin, a 30-nanometer deposited Pt layer as bottom electrode, a 720-nanometer sidewall comprising AlN, and a 50-nanometer Mo as the top electrode on the sidewall.

FIG. 9(b) illustrates the measured admittance of the FinBAR, after de-embedding excessive pad capacitance and routing resistances, and compares it with computer simulations. The FinBAR is operating in 3^{rd} width-extensional mode at 4.23 GHz showing a Q of 1,574 and keff² of 2.75%, which are both smaller compared to simulations that show a Q of 2,600 (considering intrinsic acoustic dissipation in different materials and also the energy leakage into the substrate) and k_{eff}² of 3.78%. The lower k_{eff}² and Q of the measured FinBAR can be attributed to the lower quality of sidewall AlN compared to the ideal case. Specifically, the granular texture of the sidewall AlN film results in excessive intragranular boundaries that disperse the bulk acoustic vibration and induce excessive loss and charge cancellation that reduce Q and k_{eff}².

1. A method for fabricating a fin bulk acoustic wave resonator (FinBAR), comprising:
forming a micro-fin structure on a substrate, the micro-fin structure comprising one or more sidewalls;
annealing the one or more sidewalls;
depositing a bottom electrode layer on top of the micro-fin structure;
forming a layer of aluminum nitride (AlN) on the bottom electrode layer, wherein the layer of AlN comprises a textured AlN layer with a c-axis substantially perpendicular to the one or more sidewalls; and
forming a top electrode layer on top of the layer of aluminum nitride (AlN).

2. The method of claim 1, wherein the substrate and micro-fin structure comprise silicon.

3. The method of claim 1, wherein the micro-fin structure is formed by a deep reactive ion etching technique.

4. The method of claim 1, wherein the annealing comprises hydrogen (H₂) at 1100° C.

5. The method of claim 1, further comprising:
treating the one or more sidewalls of the micro-fin structure in a radio frequency (RF) plasma discharge at a power of 70W providing argon (Ar) ion bombardment.

6. The method of claim 1, wherein the bottom electrode layer comprises platinum (Pt).

7. The method of claim 6, wherein the platinum (Pt) has a thickness of about 30 nanometers.

8. The method of claim 1, wherein the bottom electrode layer comprises molybdenum (Mo).

9. The method of claim 1, wherein the aluminum nitride layer is formed by a reactive sputtering technique at a base pressure of less than 2×10¹⁰ bar and a power of about 5.5 kW.

10. The method of claim 9, wherein the reactive sputtering technique uses Argon (Ar) and nitrogen (N₂) gas flows of about 3 and 15 standard cubic centimeters per minute (SCCM) respectively.

11. The method of claim 1, further comprising:
patterning the top electrode layer; and
etching the layer of aluminum nitride (AlN) to create access windows to the bottom electrode layer.

12. The method of claim 11, wherein etching the layer of aluminum nitride (AlN) comprises using a tetramethylammonium hydroxide (TMAH) solution at about 50° C. as an etchant.

13. The method of claim 1, further comprising:
prior to forming the bottom electrode layer, forming a seed layer positioned above the micro-fin structure, wherein the seed layer comprises a layer of aluminum nitride with about 20 nanometers thickness.

14. The method of claim 1, wherein the layer of aluminum nitride has a thickness of about 720 nanometers.

15. The method of claim 1, wherein the top electrode layer comprises molybdenum (Mo), the molybdenum (Mo) has a thickness of about 50 nanometers.

16. A fin bulk acoustic wave resonator (FinBAR), comprising:
a micro-fin structure formed on a substrate, the micro-fin structure comprising one or more sidewalls;
a bottom electrode layer deposited on top of the micro-fin structure;
a layer of aluminum nitride (AlN) formed on the bottom electrode layer, wherein the layer of AlN comprises a textured AlN layer with a c-axis substantially perpendicular to the one or more sidewalls;
a top electrode layer formed on top of the layer of aluminum nitride (AlN); and
access windows to the bottom electrode layer, wherein the access windows are created by patterning the top electrode layer and etching portions of the layer of aluminum nitride (AlN).

17. The FinBAR of claim 16, wherein the substrate and micro-fin structure comprise silicon.

18. The FinBAR of claim 16, wherein the one or more sidewalls are smoothed by annealing.

19. The FinBAR of claim 16, wherein the bottom electrode layer comprises platinum (Pt).

20. The FinBAR of claim 16, wherein the top electrode layer comprises molybdenum (Mo).
